(19) United States
(12) Patent Application Publication
(10) Pub. No.: US 2011/0089025 A1
(43) Pub. Date: Apr. 21, 2011

(54) METHOD FOR MANUFACTURING A CHIP RESISTOR HAVING A LOW RESISTANCE

(75) Inventors: Chih-Chung Yang, Kaohsiung (TW); Mei-Ling Lin, Kaohsiung (TW); Ian-Wei Chian, Kaohsiung (TW); Wen-Cheng Wu, Kaohsiung (TW); Wen-Hsiang Kong, Kaohsiung (TW); Tsai-Hu Chen, Kaohsiung (TW)

(73) Assignee: YAGEO CORPORATION, Kaohsiung (TW)

(21) Appl. No.: 12/582,154

(22) Filed: Oct. 20, 2009

(51) Int. Cl. C23C 14/14; C23C 14/34

(52) U.S. Cl. 204/192.21

(57) ABSTRACT

The present invention relates to a method for manufacturing a chip resistor having a low resistance. The method includes the following steps: (a) providing a substrate having a top surface; (b) sputtering a conducting layer directly on the top surface of the substrate, so that the conducting layer and the substrate contact each other, wherein the material of the conducting layer comprises nickel or copper; and (c) plating at least one metal layer directly on the conducting layer, so that the metal layer and the conducting layer contact each other, wherein the material of the metal layer comprises nickel or copper, and the conducting layer and the metal layer provide a resistive layer. As a result, the resistive layer has a precise pattern, and the duration of sputtering is reduced, so the yield rate and the efficiency are improved and the manufacturing cost is cut down.

### BACKGROUND OF THE INVENTION

1. Field of the Invention

The present invention relates to a method for manufacturing a chip resistor, and more particularly, to a method for manufacturing a chip resistor having a low resistance.

2. Description of the Related Art

As shown in FIG. 1, a chip resistor 1 is a passive element attached to a laminated circuit board. A method for manufacturing the conventional chip resistor 1, first, comprises providing a ceramic substrate 11 having a bottom surface 111, a pair of side surfaces 112 and a top surface 113. Then, a pair of bottom electrodes 13 are formed on the bottom surface 111 of the substrate 11. Each of the bottom electrodes 13 has an outer surface 131 aligning with the side surfaces 112 of the substrate 11. A resistive layer 14 is formed on the central area of the substrate 11, and has a pair of ends 141.

A pair of top electrodes 12 are also formed on the top surface 113 of the substrate 11. Each of the top electrodes 12 has an outer surface 122 aligning with the side surfaces 112 of the substrate 11. Besides, each of the top electrodes 12 has an inner portion 121 and an outer surface 122. The top electrodes 12 extend over the resistive layer 14, so that the inner portion 121 of the top electrodes 12 overlaps the ends 141 of the resistive layer 14.

Moreover, on the resistive layer 14, a first protective coat 15 is formed. Furthermore, a second protective coat 16 is formed on the first protective coat 15. A pair of side electrodes 17 are also formed on the side surfaces 112 of the substrate 11, the outer surfaces 122 of the top electrodes 12 and the outer surfaces 131 of the bottom electrodes 13, so that the side electrodes 17 electrically connect the top electrodes 12 and the bottom electrodes 13. A pair of first plating layers 18 are further plated to cover the bottom electrodes 13, the top electrodes 12 and the side electrodes 17, and a pair of second plating layers 19 are plated to cover the first plating layers 18, meanwhile, forming the conventional chip resistor 1.

The resistive layer 14 of a conventional thick film chip resistor is provided by screen printing a resistive paste on the ceramic substrate 11. Afterward, the conventional thick film chip resistor undergoes a drying process and a sintering process. To reduce the resistance of the conventional thick film chip resistor to about 100 mΩ, Ag, Pd or Ag—Pd alloy is usually applied to the resistive paste. However, the temperature coefficient of resistance (TCR) of Ag or Pd is about 600 to about 1000 ppm/° C., so the TCR of the conventional thick film chip resister can hardly meet the requirement of about or lower than 50 ppm/° C. Moreover, because the resistance of the conventional thick film chip resistor is determined by the size of the printing pattern, it restricts the minimum of the resistance.

On the other hand, the resistive layer 14 of a conventional thin film chip resistor is provided by sputtering a target material on the ceramic substrate 11. A mask (not shown) is first formed on the top surface 113 of the substrate 11 for defining the pattern of the resistive layer 14. Particularly, the mask is formed along the peripheral of the top surface 113 of the substrate 11 so as to form a pattern for exposing part of the top surface 113 of the substrate 11, and preferably exposing the central area of the top surface 113 of the substrate 11. Then, the resistive layer 14 having ends 141 is further formed by sputtering on the above-mentioned predetermined mask and the entire top surface 113 of the substrate 11. Afterward, the mask is removed by the combination of brushing and rinsing. The sputtered resistive layer 14 directly contacts with the ceramic substrate 11 is left due to the strong adhesion with the ceramic substrate 11, while the sputtered resistive layer 14 on the top of the mask is removed easily by brushing and rinsing. Therefore, the pattern of the resistive layer 14 is corresponding to the pattern formed by the mask. Afterward, the conventional thin film chip resistor undergoes a laser trimming process and an annealing process. To reduce the resistance of the conventional thin film chip resistor, artisans skilled in this field usually adjust an appropriate target material, an appropriate pattern or the parameters of the sputtering process. A common method for reducing the resistance is increasing the thickness of the resistive layer 14 by extending the duration of sputtering. For example, to reduce the resistance to about 100 mΩ, the duration of sputtering is about 1 hour; to reduce the resistance to about 10 mΩ, the duration of sputtering is about or more than 5 hours. However, sputtering for such a long time is costly, and not suitable for mass production. Moreover, in the long duration of sputtering, the heat accumulated on the ceramic substrate 11 is found to cause interaction between the resistive layer 14 and the mask (not shown). Such interaction distorts the sputtering pattern, thereby increasing the resistance variation and reducing the yield rate.

Therefore, it is necessary to provide a method for manufacturing a chip resistor having a low resistance to solve the above problems.

### SUMMARY OF THE INVENTION

The present invention is related to a method for manufacturing a chip resistor having a low resistance. The method comprises the following steps: (a) providing a substrate having a top surface; (b) sputtering a conducting layer directly on the top surface of the substrate, so that the conducting layer and the substrate contact each other, wherein the material of the conducting layer comprises nickel or copper; and (c) plating at least one metal layer directly on the conducting layer, so that the metal layer and the conducting layer contact each other, wherein the material of the metal layer comprises nickel or copper, and the conducting layer and the metal layer provide a resistive layer.

The resistive layer according to the invention has a precise pattern, and the duration of sputtering is reduced, so the yield rate and the efficiency are improved and the cost is cut down.

### BRIEF DESCRIPTION OF THE DRAWINGS

FIG. 1 is a cross-sectional view of a conventional chip resistor;

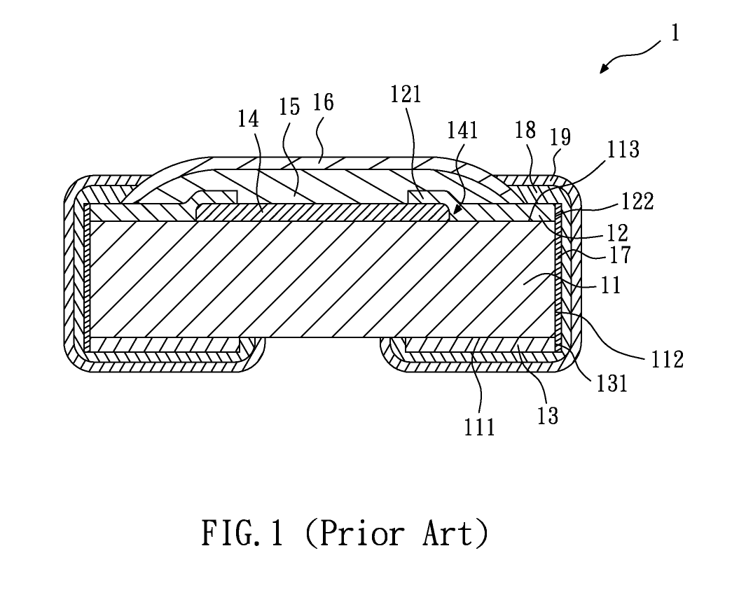

FIG. 2 is a cross-sectional view of a chip resistor according to a first embodiment of the present invention;

FIG. 3 is a cross-sectional view of the chip resistor according to the first embodiment of the present invention, wherein a resistive layer is heated;

FIG. 4 is a cross-sectional view of a chip resistor according to a second embodiment of the present invention; and

FIG. 5 is a cross-sectional view of a chip resistor according to a third embodiment of the present invention.

### DETAILED DESCRIPTION OF THE INVENTION

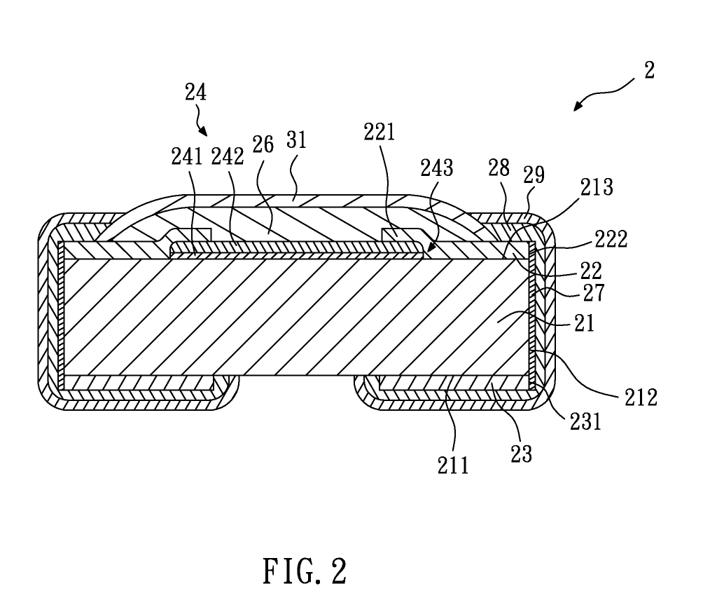

The present invention provides a method for manufacturing a chip resistor having a low resistance. According to a first embodiment of the invention, a chip resistor 2 is shown in FIG. 2. Step (a) of the method according to the invention comprises providing a substrate 21 having a bottom surface 211, a pair of side surfaces 212 and a top surface 213. The side surfaces 212 extend upward from two opposite sides of the bottom surface 211. The top surface 213 is opposite to the bottom surface 211. Preferably, the substrate 21 is a rectangular plate, and the material of the substrate 21 is ceramic, and more preferably is aluminum oxide, zirconium oxide or aluminum nitride. According to the invention, the substrate 21 is used as a supporting.

The method according to the invention preferably comprises a step of forming a pair of bottom electrodes 23 on the bottom surface 211 of the substrate 21 after step (a). The bottom electrodes 23 are conductive and separated; that is, they are not connected to each other. Each of the bottom electrodes 23 has an outer surface 231. The term “outer” as used herein refers to the direction away from the central area of the substrate 21. The outer surfaces 231 of the bottom electrodes 23 align with the side surfaces 212 of the substrate 21. In one preferred embodiment of the invention, the bottom electrodes 23 are formed by printing.

Step (b) of the method according to the invention comprises directly sputtering a conducting layer 241 on the central area of the top surface 213 of the substrate 21, so that the conducting layer 241 and the substrate 21 contact each other. The action of sputtering is to bombard a target material with energetic ions (called ionized gas), and the atoms of the target material are ejected and deposited onto the substrate 21. In one preferred embodiment of the invention, a mask (not shown) is first formed on the top surface 213 of the substrate 21 for defining the pattern of the conducting layer 241 before step (b). Particularly, the mask is formed along the peripheral of the top surface 213 of the substrate 21 so as to form a pattern for exposing part of the top surface 213 of the substrate 21, and preferably exposing the central area of the top surface 213 of the substrate 21. Then, the conducting layer 241 is formed by sputtering on the above-mentioned predetermined mask and the entire top surface 213 of the substrate 21. Afterward, the mask is removed by the combination of brushing and rinsing. The sputtered conducting layer 241 directly contacts with the substrate 21 is left due to the strong adhesion with the substrate 21, while the sputtered conducting layer 241 on the top of the mask is removed easily by brushing and rinsing. Therefore, the pattern of the conducting layer 241 is corresponding to the pattern formed by the mask.

The material of the conducting layer 241 according to the invention comprises nickel or copper. Preferably, the conducting layer 241 further comprises manganese, tin, chromium or silicon. In one preferred embodiment of the invention, the conducting layer 241 is a Cu—Ni alloy, and comprises about 45% to about 75% of copper, and about 25% to about 55% of nickel. In another preferred embodiment of the invention, the conducting layer 241 is a Cu—Mn alloy, and comprises about 87% of copper, and about 13% of manganese. In still another preferred embodiment of the invention, the conducting layer 241 is a Cu—Mn—Sn alloy, and comprises about 87% of copper, about 12% of manganese, and about 1% of tin. In still another preferred embodiment of the invention, the conducting layer 241 is a Ni—Cr alloy, and comprises about 80% of nickel and about 20% of chromium. In still another preferred embodiment of the invention, the conducting layer 241 is a Ni—Cr—Si alloy, and comprises about 50% to about 55% of nickel, about 33% to about 45% of chromium, and about 5% to about 12% of silicon. In still another preferred embodiment of the invention, the conducting layer 241 is a Cu—Ni—Mn alloy, and comprises about 44% to about 75% of copper, about 24% to about 55% of nickel, and about 1% of manganese.

Step (c) of the method according to the invention comprises directly plating at least one metal layer 242 on the conducting layer 241, so that the metal layer 242 and the conducting layer 241 contact each other. The plating is an electro-deposition process, wherein a direct current flows through an anode, leading to the dissolution of the anode material into an electroyte solution. The dissolved metal ions of a given material in the electroyte solution are reduced and deposited onto the surface of the conducting layer 241. The material of the metal layer 242 according to the invention comprises nickel or copper, and the conducting layer 241 and the metal layer 242 provide a resistive layer 24 having a pair of ends 243.

In one preferred embodiment of the invention, a plurality of metal layers 242 are plated, and the material of the metal layers 242 is alternately copper and nickel. Preferably, the material of the most outer metal layer 242 is nickel, because the chemical resistance of nickel is better than that of copper. In another embodiment, the material of the conducting layer 241 comprises copper, and the material of the metal layer 242 is nickel. In still another preferred embodiment of the invention, the material of the conducting layer 241 comprises nickel, and the material of the metal layer 242 is copper.

According to the invention, the conducting layer 241 is formed by sputtering. Compared with the conventional screen printing manner for producing the resistive layer 14 of the conventional thick film chip resistor, the sputtering manner for producing the conducting layer 241 according to the invention provides a more precise pattern, which leads to a lower resistance variation than that of the conventional thick film chip resistor. Moreover, because the metal layer 242 is plated on the conducting layer 241, the resistance of the chip resistor 2 and the thickness of the resistive layer 24 are mainly determined by the duration of the plating of the metal layer 242, and the thickness of the conducting layer 241. Thus, the heat due to long sputtering duration and accumulated on the substrate 21 is significantly reduced. Besides, the problem with distorted sputtering pattern in the conventional thin film chip resistor is solved by avoiding the interaction between the resistive layer 24 and the mask. Therefore, the method according to the invention applies to both a thick film chip resistor and a thin film chip resistor.

As a result, the resistive layer 24 has a precise pattern, and the duration of sputtering is reduced, so the yield rate and the efficiency are improved, the manufacturing cost is cut down, and the resistance of the chip resistor is reduced.

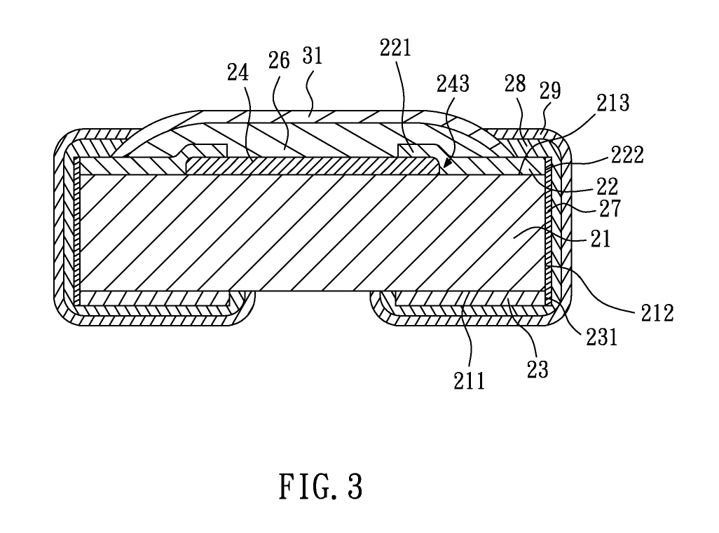

Preferably, the method further comprises a step of heating the resistive layer 24 after step (c), wherein the resistive layer 24 is preferably heated at a temperature of about 600° C. to about 800° C. In another aspect, the resistive layer 24 is heated for about 10 minutes to about 20 minutes. The heating process provides energy for Ni and/or Cu atoms of the conducting and/or metal layer 242 to overcome the thermal activation energy barrier, and Ni and/or Cu atoms start to diffuse, so that the conducting layer 241 and the metal layer 242 forms a single-phase alloy. Because the interface between the conducting layer 241 and the metal layer 242 is obscure, the resistive layer 24 looks like a single layer, as shown in FIG. 3.

The method according to the invention preferably comprises a step of forming a pair of top electrodes 22 on the top surface 213 of the substrate 21. The top electrodes 22 are conductive and separated; that is, they are not connected to each other. Each of the top electrodes 22 has an inner portion 221 and an outer surface 222. The top electrodes 22 extend over the resistive layer 24, so that the inner portion 221 of the top electrodes 22 overlaps the ends 243 of the resistive layer 24. The outer surface 222 of the top electrodes 22 aligns with the side surfaces 212 of the substrate 21, so that the top electrodes 22 correspond to the bottom electrodes 23. In one preferred embodiment of the invention, the top electrodes 22 are formed by printing.

The method according to the invention preferably comprises a step of forming a first protective coat 26 to cover the resistive layer 24, so that the resistive layer 24 is isolated. The first protective coat 26 covers part of the top electrodes 22; that is, the first protective coat 26 contacts the top electrodes 22.

The method according to the invention preferably comprises a step of forming a second protective coat 31 on the first protective coat 26. The second protective coat 31 covers the first protective coat 26 and part of the top electrodes 22, so that the resistive layer 24 and the first protective coat 26 are isolated. The material of the second protective coat 31 may be the same as or different from that of the first protective coat 26. When the first protective coat 26 and the second protective coat 31 are made of the same material, the interface thereof is obscure, so that they look like one protective coat.

The method according to the invention preferably comprises a step of forming a pair of side electrodes 27 on the side surfaces 212 of the substrate 21, the outer surfaces 222 of the top electrodes 22 and the outer surfaces 231 of the bottom electrodes 23, so that the side electrodes 27 electrically connect the top electrodes 22 and the bottom electrodes 23. The side electrodes 27 are made of conductive material. In one preferred embodiment of the invention, the side electrodes 27 are formed by coating. In another preferred embodiment of the invention, the side electrodes 27 are formed by sputtering.

The method according to the invention preferably comprises a step of plating a pair of first plating layers 28 to cover the bottom electrodes 23, the top electrodes 22 and the side electrodes 27. In one preferred embodiment of the invention, the material of the first plating layers 28 is nickel, and the first plating layers 28 are formed by plating.

The method according to the invention preferably comprises a step of plating a pair of second plating layers 29 to cover the first plating layers 28. In one preferred embodiment of the invention, the material of the second plating layers 29 is tin, and the second plating layers 29 are formed by plating.

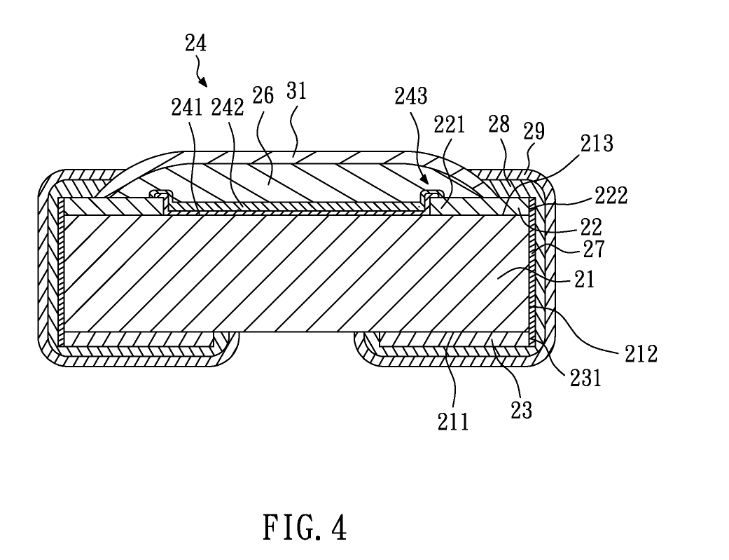

In another preferred embodiment of the invention, as shown in FIG. 4, the top electrodes 22 are formed on the top surface 213 of the substrate 21 before the resistive layer 24 is provided; that is, after the step of forming the bottom electrodes 23. The step of forming the top electrodes 22 is conducted before step (b) and step (c) which jointly provide the resistive layer 24. Therefore, the resistive layer 24 extends over the top electrodes 22, so that the ends 243 of the resistive layer 24 overlap the inner portion 221 of the top electrodes 22.

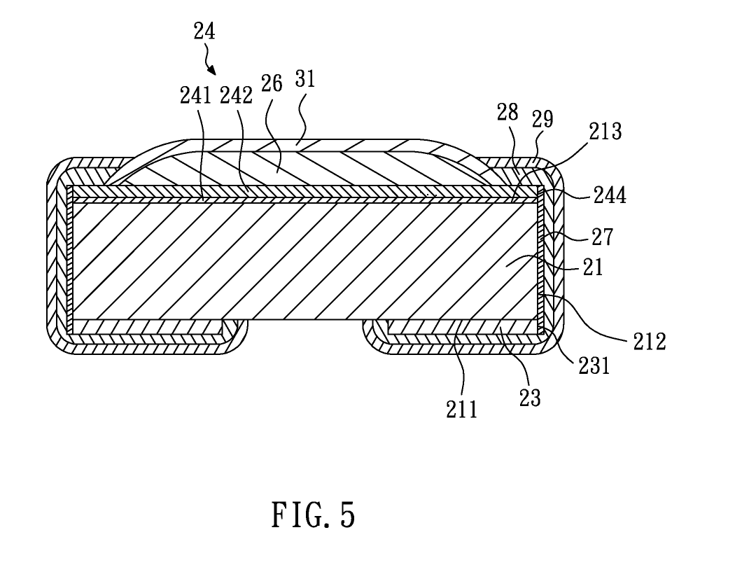

In still another preferred embodiment of the invention, as shown in FIG. 5, after step (b) and step (c) which jointly provide the resistive layer 24, the step of forming a first protective coat 26 is conducted. Therefore, the first protective coat 26 covers only part of the resistive layer 24. The side electrodes 27 are also formed on the side surfaces 212 of the substrate 21, a pair of side surfaces 244 of the resistive layer 24 and the outer surfaces 231 of the bottom electrodes 23, so that the side electrodes 27 electrically connect the resistive layer 24 and the bottom electrodes 23.

While embodiments of the present invention have been illustrated and described, various modifications and improvements can be made by persons skilled in the art. The embodiments of the present invention are therefore described in an illustrative and not restrictive sense. It is intended that the present invention is not limited to the particular forms as illustrated, and that all the modifications not departing from the spirit and scope of the present invention are within the scope defined in the appended claims.

What is claimed is:

1. A method for manufacturing a chip resistor having a low resistance, which comprises:
(a) providing a substrate having a top surface;
(b) sputtering a conducting layer directly on the top surface of the substrate, so that the conducting layer and the substrate contact each other, wherein the material of the conducting layer comprises nickel or copper; and
(c) plating at least one metal layer directly on the conducting layer, so that the metal layer and the conducting layer contact each other, wherein the material of the metal layer comprises nickel or copper, and the conducting layer and the metal layer provide a resistive layer.

2. The method as claimed in claim 1, wherein in step (a), the material of the substrate is aluminum oxide, zirconium oxide or aluminum nitride.

3. The method as claimed in claim 1, wherein in step (b), the conducting layer is an alloy.

4. The method as claimed in claim 3, wherein the conducting layer is a Cu—Ni alloy, and comprises about 45% to about 75% of copper, and about 25% to about 55% of nickel.

5. The method as claimed in claim 3, wherein the conducting layer further comprises manganese, tin, chromium or silicon.

6. The method as claimed in claim 5, wherein the conducting layer is a Cu—Ni—Mn alloy, and comprises about 44% to about 75% of copper, about 24% to about 55% of nickel, and about 1% of manganese.

7. The method as claimed in claim 5, wherein the conducting layer is a Cu—Mn alloy, and comprises about 87% of copper, and about 13% of manganese.

8. The method as claimed in claim 5, wherein the conducting layer is a Cu—Mn—Sn alloy, and comprises about 87% of copper, about 12% of manganese, and about 1% of tin.

9. The method as claimed in claim 5, wherein the conducting layer is a Ni—Cr—Si alloy, and comprises about 50% to about 55% of nickel, about 33% to about 45% of chromium, and about 5% to about 12% of silicon.

10. The method as claimed in claim 5, wherein the conducting layer is a Ni—Cr alloy, and comprises about 80% of nickel and about 20% of chromium.

11. The method as claimed in claim 1, wherein the material of the conducting layer comprises copper, and the material of the metal layer is nickel.

12. The method as claimed in claim 1, wherein the material of the conducting layer comprises nickel, and the material of the metal layer is copper.

13. The method as claimed in claim 1, wherein in step (c), a plurality of metal layers are plated, and the material of the metal layers is alternately copper and nickel.

14. The method as claimed in claim 1, wherein in step (c), a plurality of metal layers are plated, and the material of the most outer metal layer is nickel.

15. The method as claimed in claim 1, further comprising a step of heating the resistive layer after step (c).

16. The method as claimed in claim 15, wherein the resistive layer is heated at a temperature of about 600° C. to about 800° C.

17. The method as claimed in claim 15, wherein the resistive layer is heated for about 10 minutes to about 20 minutes.
